(19) United States
(12) Patent Application Publication
(10) Pub. No.: US 2025/0201776 A1
(43) Pub. Date: Jun. 19, 2025

(54) SEMICONDUCTOR PACKAGE AND METHOD FOR MANUFACTURING THE SAME

(71) Applicant: SAMSUNG ELECTRONICS CO., LTD., SUWON-SI (KR)

(72) Inventors: SEOKBEOM YONG, Suwon-si (KR); EUNKYEONG PARK, Suwon-si (KR); SANG SUB SONG, Suwon-si (KR); SUNGOH AHN, Suwon-si (KR); SEULGI YU, Suwon-si (KR)

(21) Appl. No.: 18/769,556

(22) Filed: Jul. 11, 2024

(30) Foreign Application Priority Data
Dec. 15, 2023 (KR) 10-2023-0183427

(51) Int. Cl. H01L 25/065; H01L 21/822; H01L 23/00; H01L 27/08

(52) U.S. Cl. CPC H01L 25/0657; H01L 24/08; H01L 24/16; H01L 24/32; H01L 24/73; H01L 24/80; H01L 24/94; H10D 84/038; H10D 84/212; H10D 88/01; H01L 2224/08145; H01L 2224/16227; H01L 2224/16238; H01L 2224/32225; H01L 2224/73204; H01L 2224/80895; H01L 2224/80896; H01L 2224/94; H01L 2225/06517; H01L 2225/06541; H01L 2924/1431; H01L 2924/37001

(57) ABSTRACT

A semiconductor package including: a substrate that includes a wiring line; and a 3-dimensional integrated circuit structure on the substrate, the 3-dimensional integrated circuit structure including a first die and a second die on the first die, the first die including a first capacitor structure having a defect, a second capacitor structure free of defects, and a plurality of through silicon vias connected to the second die, wherein the first capacitor structure is electrically separated from the second die, and the second capacitor structure is electrically connected to a corresponding through silicon via among the plurality of through silicon vias through the wiring line.

### CROSS-REFERENCE TO RELATED APPLICATION

This application claims priority under 35 U.S.C. § 119 to Korean Patent Application No. 10-2023-0183427 filed in the Korean Intellectual Property Office on Dec. 15, 2023, the disclosure of which is incorporated by reference herein in its entirety.

### (a) TECHNICAL FIELD

The present disclosure relates to a semiconductor package and a manufacturing method thereof.

### (b) DESCRIPTION OF THE RELATED ART

As semiconductor technology advances, the demand for semiconductor packages that include logic dies with high-performance circuits and higher speed digital signals is increasing. In such semiconductor packages, power integrity (PI) characteristics are crucial. To improve the power integrity, it is necessary to implement high-capacity capacitors within the semiconductor package. To meet these requirements, a 3-dimensional integrated circuit (3DIC) chip has been developed, which includes a lower capacitor die and an upper logic die to provide the necessary capacitance for the logic die.

These 3-dimensional integrated circuit chips form a wafer stacking structure by bonding a wafer including capacitor dies to a wafer including logic dies. The stacked wafer structure is then sawed and singulated to manufacture a singulated die stacking structure.

Due to the structural feature of bonding the lower capacitor die and the upper logic die, a defect in the capacitor die results in the entire 3-dimensional integrated circuit chip being deemed defective, even if the logic die is normal. The logic die, which handles operations and calculations within the 3-dimensional integrated circuit chip, is not only more critical in terms of function than the capacitor die, but also more expensive to manufacture. Consequently, discarding a normally operating logic die due to a defective capacitor leads to significant losses, reduced yield and increased manufacturing costs for 3-dimensional integrated circuit chips.

Therefore, there is a need to develop new semiconductor package technology these issues associated with 3-dimensional integrated circuit chips that include a lower capacitor die and an upper logic die.

### SUMMARY OF THE INVENTION

Embodiments of the present invention provide a semiconductor package that divides the plane of a capacitor die into a plurality of regions. Each of the plurality of regions contains a capacitor structure. If a defect is detected in the capacitor structure, the region with the defective capacitor structure is isolated using a wire structure of the substrate. Additionally, a method of manufacturing the semiconductor package is provided.

An embodiment of the present invention provides a semiconductor package including: a substrate that includes a wiring line; and a 3-dimensional integrated circuit structure on the substrate, the 3-dimensional integrated circuit structure including a first die and a second die on the first die, the first die including a first capacitor structure having a defect, a second capacitor structure free of defects, and a plurality of through silicon vias connected to the second die, wherein the first capacitor structure is electrically separated from the second die, and the second capacitor structure is electrically connected to a corresponding through silicon via among the plurality of through silicon vias through the wiring line.

An embodiment of the present invention provides a semiconductor package including: a substrate that includes one or more wiring lines; and a 3-dimensional integrated circuit structure on the substrate, wherein the 3-dimensional integrated circuit includes: a first die that includes one or more first capacitor structures, one or more second capacitor structures, one or more first through silicon vias, and one or more second through silicon vias, the first die including one or more first regions and one or more second regions defined by dividing the plane of the first die, each of the one or more first capacitor structures and each of the one or more first through silicon vias disposed in each of the one or more first regions, each of the one or more second capacitor structures and each of the one or more second through silicon vias disposed in each of the one or more second regions, the one or more first capacitor structures having a defect, and the one or more second capacitor structures being free of a defect; and a second die on the first die, the second die connected to the one or more first through silicon vias and the one or more second through silicon vias, the first capacitor structure and the first through silicon via in each of the one or more first regions are electrically separated from each other, and the second capacitor structure and the second through silicon via in each of the one or more second regions are electrically connected through each of the one or more wiring lines.

An embodiment of the present invention provides a semiconductor package manufacturing method including: forming a plurality of capacitor dies in a first wafer, each of the plurality of capacitor dies including a plurality of capacitor structures and a plurality of through silicon vias; determining whether each of the plurality of capacitor structures has a defect; bonding a second wafer that includes a plurality of logic dies to the first wafer, each of the plurality of logic dies connected to the plurality of through silicon vias; forming a 3-dimensional integrated circuit structure by singulating the bonded first and second wafers; providing a substrate where a defective capacitor structure is connected only to a ground and a defect-free capacitor structure is electrically connected to a corresponding through silicon via among the plurality of through silicon vias; and bonding a 3-dimensional integrated circuit structure on the substrate.

When there is a defect in the capacitor structure, the capacitor die including the defective capacitor structure can still be used normally by closing (isolating) the region where the defective capacitor structure is located using the wire structure of the substrate. This allows 3-dimensional integrated circuit chips, which include a defective capacitor structure die and a normal logic die to function properly.

Therefore, this approach addresses the yield reduction problem in conventional 3-dimensional integrated circuit chips caused by capacitor dies with defective capacitor structures. Additionally, this approach ensures that all normal logic dies are implemented within fully functional (normal) 3-dimensional integrated circuit chips, thereby reducing the manufacturing cost of these chips.

### BRIEF DESCRIPTION OF THE DRAWINGS

FIG. 1 is a cross-sectional view of a wafer including conventional defective capacitor dies.

FIG. 2 shows a circuit of the semiconductor package including the conventional defective capacitor die.

FIG. 3 is a cross-sectional view of a wafer including a defective capacitor dies according to an embodiment of the present invention.

FIG. 4 shows a circuit of a semiconductor package including a defective capacitor die.

FIG. 5 is a cross-sectional view of the semiconductor package according to an embodiment of the present invention.

FIG. 6 is a cross-sectional view of the capacitor structure according to an embodiment of the present invention.

FIGS. 7, 8, 9, 10, 11, 12 and 13 are cross-sectional views provided for description of a method for manufacturing the semiconductor package of FIG. 5.

### DETAILED DESCRIPTION OF THE EMBODIMENTS

Hereinafter, various embodiments of the present invention will be described in detail with reference to the accompanying drawings. These descriptions will enable a person of an ordinary skill in the relevant technical field to easily implement the invention. The present invention may be implemented in various forms and is not limited to the embodiments described herein.

For clarity, parts irrelevant to the description have been omitted, and the same reference signs are used to designate the same or similar constituent elements throughout the specification.

In addition, the sizes and thicknesses of each component shown in the drawings are indicated arbitrarily for better understanding and ease of description. Therefore, the present invention is not necessarily limited to these drawings.

Throughout the specification, when it is described that an element is “connected” to another element, this includes both “directly connected” and “indirectly connected” through another member. In addition, unless explicitly stated to the contrary, the word “comprise” and its variations such as “comprises” or “comprising” will be understood to imply the inclusion of stated elements without excluding any other elements.

It will be understood that when an element such as a layer, film, region, or substrate is referred to as being “on” another element, it can be directly on the other element or intervening elements may also be present. In contrast, when an element is referred to as being “directly on” another element, no intervening elements are present. Further, the term “on” a target element will be understood to mean positioned above or below the target element, and will not necessarily mean positioned “at an upper side” based on the opposite direction of gravity.

Further, throughout the specification, the phrase “on a plane” means viewing a target portion from the top, and the phrase “on a cross-section” means viewing a cross-section formed by vertically cutting a target portion from the side.

Hereinafter, a semiconductor package according to an embodiment of the present invention and a method for manufacturing the same will be described.

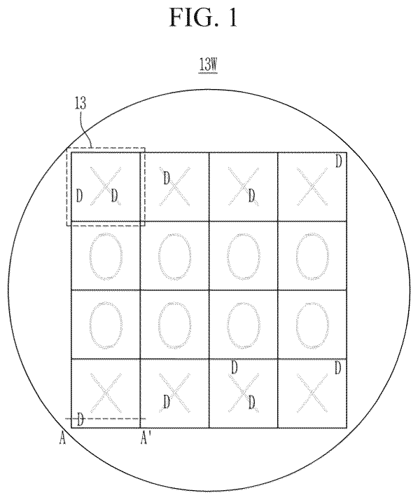

FIG. 1 is a cross-sectional view of a wafer 13W including conventional defective capacitor dies 13.

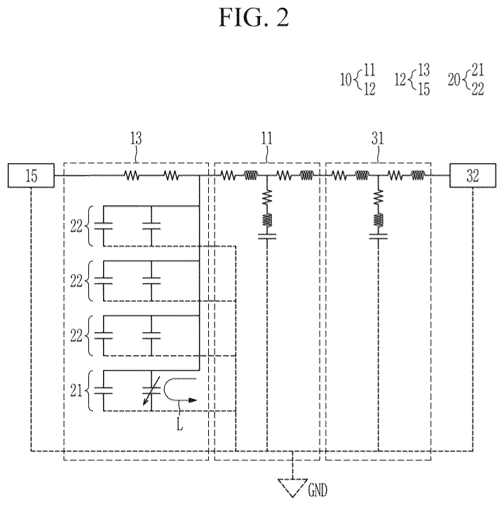

Referring to FIG. 1, the wafer 13W includes capacitor dies 13. The capacitor dies 13 include capacitor structures 20 (refer to FIG. 2). Conventionally, if one or more of the capacitor structures 20 has a defect D, the entire capacitor die 13, which includes the defective capacitor structure 21, becomes unusable. In FIG. 1, the wafer 13W contains a capacitor die 13 marked with an “X” to indicate the presence of a defective capacitor structure 21. Conversely, a capacitor die 13 that includes capacitor structures 22 that are defect free and usable is marked with an “O”.

A 3-dimensional integrated circuit (3DIC) chip 12 (refer to FIG. 2) is formed through a process that forms a wafer stacking structure. This process involves bonding a wafer 13W, which includes capacitor dies 13, to a wafer including logic dies 15 (refer to FIG. 2). Subsequently, a singulated die stacking structure is formed by sawing and singulating the wafer stacking structure.

Due to the structural characteristics of the 3-dimensional integrated circuit chip 12, which is manufactured by bonding the wafer 13W including the capacitor dies 13 and the wafer including logic dies 15, the entire 3-dimensional integrated circuit chip 12 is determined to be defective if an unusable (X marked) capacitor die 13, including the capacitor structure 21 with the defect D is bonded with a normal logic die 15. Consequently, the normal logic die 15 is also discarded.

The logic die 15, which is responsible for operation and calculation within the 3-dimensional integrated circuit chip 12, is more critical in terms of function than the capacitor die 13 that provides capacitance. Additionally, since the logic die 15 undergoes more manufacturing processes and is also more expensive to manufacture, discarding a normally operating logic die due to a defective capacitor die 13 results in significant losses. This leads to a decrease in yield and an increase in manufacturing costs in the manufacturing of the 3-dimensional integrated circuit chips 12.

FIG. 2 shows a circuit of the semiconductor package 10 including the conventional defective capacitor die 13. The circuit of the capacitor die 13 of FIG. 2 relates to the capacitor die 13 taken along the line A-A′ of FIG. 1.

Referring to FIG. 2, the semiconductor package 10 includes a substrate 11, a capacitor die 13, and a logic die 15. The semiconductor package 10 is connected to a board 31 and a power management integrated circuit (PMIC) 32, and receives electric power from the PMIC 32. When a defect D occurs in some of the capacitor structures 20 in the capacitor die 13, a current leakage L occurs due a DC short circuit in the capacitor structure 21 where the defect D is located. In this case, the electric power transmitted from the PMIC 32 through the board 31 and substrate 11 and exits to ground through the defective capacitor structure of capacitor die 13. As a result, the logic die 15 cannot operate.

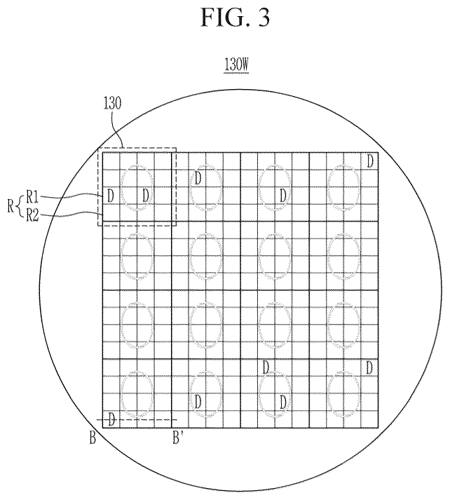

FIG. 3 is a cross-sectional view of a wafer 130W including capacitor dies 130 including a defect D according to an embodiment of the present invention.

Referring to FIG. 3, the wafer 130W includes capacitor dies (first dies) 130. Each of the capacitor dies 130 include N regions R1 defined by dividing the plane of the capacitor die 130. N includes natural numbers of 2 or more. In FIG. 3, as an embodiment, it is illustrated that N=16 and the capacitor die 130 includes 16 regions R. The regions R of the capacitor die 130 may vary in size. To define the regions R of the capacitor die 130, the lines dividing the plane of the capacitor die 130 may or may not be parallel to the scribe lines of the capacitor die 130.

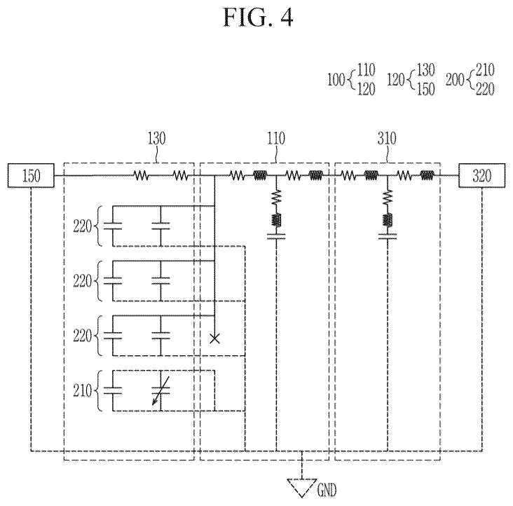

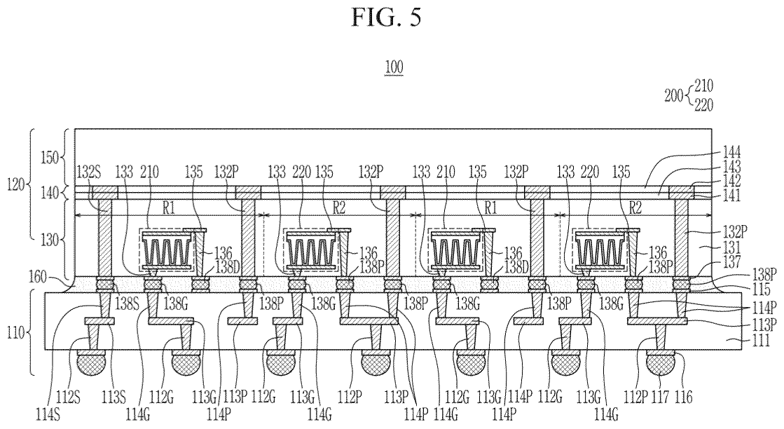

The wafer 130W includes the capacitor dies 130. The capacitor dies 130 include capacitor structures 200 (refer to FIG. 4 and FIG. 5). Each of the capacitor structures 200 is disposed within each region R defined by dividing the plane of the capacitor die 130. When the number of capacitor structures 200 is N, the number of regions R is also N.

After the capacitor structures 200 are formed in the wafer 130W, an electrical die sorting (EDS) process is performed on each of the capacitor structures 200 to determine whether the singulated capacitor structures 200 have the defect D. Following the EDS process, the capacitor structure 200 identified with the defect D is designated as a defective capacitor structure 210, while the capacitor structure 200 without the defect D is designated as a normal capacitor structure 220. A region R containing the defective capacitor structure 210 is defined as a first region R1, and a region R containing the normal capacitor structure 220 is defined as a second region R2.

The capacitor die 130 according to the present disclosure can be used even if it includes the defective capacitor structure 210, as indicated by the mark (O). When the capacitor die 130 including the defective capacitor structure 210 is bonded to the normal logic die (second die) 150 to form a 3-dimensional integrated circuit (3DIC) structure 120 (refer to FIG. 4 and FIG. 5), the 3DIC structure 120 is determined to be a normal chip.

FIG. 4 shows a circuit of a semiconductor package 100 including a defective capacitor die 130. The circuit of the capacitor die 130 of FIG. 4 relates to the capacitor die 130 taken along the line B-B′ of FIG. 3.

Referring to FIG. 4, the semiconductor package 100 includes a substrate 110, the capacitor die 130, and a logic die 150. The semiconductor package 100 is connected to a board 310 and a PMIC 320, and receives electric power from the PMIC 320. The capacitor die 130 includes capacitor structures 200. The capacitor structure 200 includes a defective capacitor structure (first capacitor structure) 210 and a normal capacitor structure (second capacitor structure) 220. in a conventional capacitor structure, the connection is made to an electric power wiring line disposed within the capacitor die. However, the capacitor structure 200 according to the present disclosure is not connected to an electric power wiring line within the capacitor die 130. Instead, it is connected to an electric power wiring line disposed within the substrate 110.

The substrate 110 does not include an electric power wiring line connecting a defective capacitor structure 210 to an electric power supply line within a region corresponding to the first region R1 where the defective capacitor structure 210 is located. Instead, the substrate 110 includes a ground wiring line 113G (refer to FIG. 5) that connects the defective capacitor structure 210 to the ground. The defective capacitor structure 210 is solely connected to the ground through the substrate 110. Consequently, there is no leakage L of electric power transmitted from the PMIC 320 through the board 310 and the substrate 110 from the defective capacitor structure 210, as a DC short circuit does not occur.

The substrate 110 includes an electric power wiring line 113P (refer to FIG. 5) connecting the normal capacitor structure 220 to an electric power supply line within the region corresponding to the second region R2 where the normal capacitor structure 220 is located. The normal capacitor structure 220 receives electric power transmitted from the PMIC 320 through the board 310 and the substrate 110, allowing it to operate normally. Consequently, the logic die 150 also operates normally.

FIG. 5 is a cross-sectional view of the semiconductor package 100 according to an embodiment of the present invention.

Referring to FIG. 5, the semiconductor package 100 includes a substrate 110, a 3DIC structure 120, a connection member 138, and an insulation member 160. In an embodiment, the semiconductor package 100 may be manufactured using a fan out wafer level package (FOWLP) or fan out panel level package (FOPLP) technology. According to the present disclosure, an “S” is added to a reference numeral of a component corresponding to a wire path transmitting a signal, “P” is added to a reference numeral of a component corresponding to a wire path transmitting electric power, and “G” is added to a reference numeral of a component corresponding to a wire path connected to the ground.

The substrate 110 is placed below the 3DIC structure 120. The substrate 110 includes a dielectric material 111, a first via 112, a wiring line 113 and a second via 114 in the dielectric material 111, a bonding pad 115 on an upper surface of the dielectric material 111, and a connection pad 116 and a connection member 117 on a bottom surface of the dielectric material 111. In an embodiment, the substrate 110 may include a printed circuit board (PCB), a redistribution layer (RDL) structure, or an interposer. In an embodiment, the interposer may include an organic interposer, a silicon interposer, or a composite interposer. In another embodiment, a substrate 110 that includes fewer or more wiring lines, vias, bonding pads, connection pads, and connection members is included in the scope of the present disclosure.

The dielectric material 111 protects and insulates the first vias 112, the wiring lines 113, and the second vias 114. The bonding pads 115 and the insulating member 160 are disposed on the upper surface of the dielectric material 111. The connection pads 116 are placed on the bottom surface of the dielectric material 111.

In an embodiment, dielectric material 111 may include a photo imagable dielectric (PID) used in a redistribution layer process. The PID is a material that can form fine patterns through the application of a photolithography process. In an embodiment, the PID may include a polyimide-based photoactive polymer, a novolak-based photoactive polymer, polybenzoxazole, a silicon-based polymer, an acrylate-based polymer, or an epoxy-based polymer. In an embodiment, the dielectric material 111 may include silicon or silicon oxide. In an embodiment, the dielectric material 111 may include a thermosetting resin such as epoxy resin, a thermoplastic resin such as polyimide, or a material in which these resins are mixed with an inorganic filler. In an embodiment, the dielectric material 111 may include resin impregnated in a core material such as glass fiber (glass fiber, glass cloth, glass fabric, and the like) along with an inorganic filler. In an embodiment, the dielectric material 111 may include prepreg, Ajinomoto build-up film (ABF), FR-4, and bismaleimide triazine (BT).

Each of the first vias 112 is placed between the wiring line 113 and the connection pad 116. Each of the first vias 112 electrically connects the wiring line 113 to the connection member 117 connected to the connection pad 116 in the vertical direction. Each of the wiring lines 113 is placed between the first via 112 and the second via 114. Each of the wiring lines 113 electrically connects the first via 112 and the second via 114 in the horizontal direction. Each of the second vias 114 is placed between the wiring line 113 and the bonding pad 115. Each of the second vias 114 electrically connects the bonding pad 115 to the wiring line 113 in the vertical direction. In an embodiment, the first via 112, the wiring line 113, and the second via 114 may each include at least one of copper, aluminum, tungsten, nickel, gold, tin, titanium, and alloys thereof.

The bonding pads 115 are disposed on the upper surface of the dielectric material 111. Each of the bonding pads 115 is disposed between the second via 114 and the connection member 138. Each of the bonding pads 115 electrically connects the connection member 138 to the second via 114. In one embodiment, the bonding pad 115 may include at least one of copper, nickel, zinc, gold, silver, platinum, palladium, chromium, titanium, and alloys thereof.

The connection pads 116 are disposed on the bottom surface of the dielectric material 111. Each of the connection pads 116 is disposed between the first via 112 and the connection member 117. Each of the connection pads 116 electrically connects the first via 112 to the connection member 117. In an embodiment, the connection pad 116 may include at least one of copper, nickel, zinc, gold, silver, platinum, palladium, chromium, titanium, and alloys thereof.

Each of the connection members 117 is placed below each of the connection pads 116. The connection members 117 electrically connect the semiconductor package 100 to external devices (board 310 (refer to FIG. 4) and power management integrated circuit 320 (refer to FIG. 4), and the like). In an embodiment, the connection member 117 may include a micro bump or solder ball. In an embodiment, the connecting member 117 may include at least one of tin, silver, lead, nickel, copper, or an alloy thereof.

The 3DIC structure 120 is disposed on the substrate 110. The 3DIC structure 120 includes a capacitor die 130, an interconnection structure 140, and a logic die 150.

The 3DIC structure 120 is a technology that implements semiconductor dies as a 3-dimensional single chip by changing the conventional method of arranging and connecting semiconductor dies horizontally to arranging and connecting them vertically. Stacking the semiconductor dies vertically allows more elements to be placed within the same area of the wafer, lowering manufacturing costs and increasing performance compared to the conventional horizontal arrangement of semiconductor dies.

In the 3DIC structure 120 according to the present disclosure, a distance between the capacitor die 130 and the logic die 150, which includes a high-performance circuit requiring the high-capacity capacitance, can be reduced by disposing the capacitor structures 200 and through silicon vias (TSV) 132 on the capacitor die 130 and disposing the logic die 150 on the capacitor die 130. In addition, the through silicon vias (TSV) 132 within the capacitor die 130 connect the substrate 110 and the logic die 150, thereby increasing the speed at which signals and electric power are exchanged between the substrate 110 and logic die 150.

The capacitor die 130 includes a dielectric material 131, a capacitor structure 200, through silicon vias 132, a first contact plug 133, a contact wire 135, and a second contact plug 136 in the dielectric material 131, and connection pads 137 on a bottom surface of the dielectric material 131.

The dielectric material 131 protects and insulates the capacitor structure 200, the through silicon vias 132, the first contact plug 133, the contact wire 135, and the second contact plug 136. The interconnection structure 140 is disposed on an upper surface of the dielectric material 131. The connection pads 137 and the insulation member 160 are disposed on the bottom surface of the dielectric material 131. In an embodiment, the dielectric material 131 may include the same material as the wafer. In an embodiment, the dielectric material 131 may include silicon or silicon oxide.

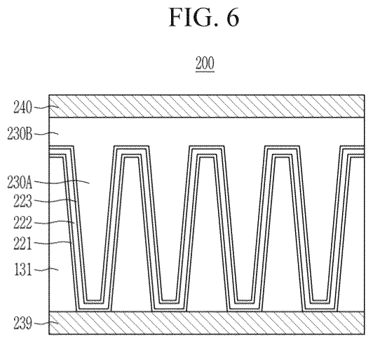

Each of the capacitor structures 200 is disposed within each region R defined by dividing the plane of the capacitor die 130. A defective capacitor structure 210 is disposed in a first region R1, and a normal capacitor structure 220 is disposed in a second region R2. In an embodiment, the capacitor structure 200 may include an integrated stack capacitor (ISC) structure. The integrated stack capacitor structure includes a lower plate layer 239, a lower electrode 221, a dielectric layer 222, an upper electrode 223, an interconnection member 230, and an upper plate layer 240 (refer to FIG. 6). The defective capacitor structure 210 is not connected to an electric power wiring line 113P of the substrate 110. The defective capacitor structure 210 is electrically separated from the logic die 150. The defective capacitor structure 210 is electrically separated from an electric power through-silicon via (first through-silicon via) 132P, which is disposed in the same first region R1 (connected to logic die 150) as the defective capacitor structure 210. The defective capacitor structure 210 is connected to the first contact plug 133, and though the first contact plug 133, the defective capacitor structure 210 is connected to the ground through the connection pad 137, a ground connection member 138G, a second ground via 114G of the substrate 110, a ground wiring line 113G of the substrate 110, and first ground via 112G of the substrate 110. The defective capacitor structure 210 is connected to the contact wire 135, and further connected to a dummy connection member 138D through the second contact plug 136 and the connection pad 137. In an embodiment, the defective capacitor structure 210 is connected only to the ground.

The first contact plug 133 in the first region R1 is placed between the defective capacitor structure 210 and the connection pad 137. The first contact plug 133 in the first region R1 connects the defective capacitor structure 210 to the connection pad 137. The contact wire 135 in the first region R1 is placed between the defective capacitor structure 210 and the second contact plug 136. The first contact wire 135 in the first region R1 connects the defective capacitor structure 210 to the second contact plug 136. The second contact plug 136 in the first region R1 is placed between the contact wire 135 and the connection pad 137. The second contact plug 136 in the first region R1 connects the contact wire 135 to the connection pad 137. In an embodiment, the first contact plug 133, the contact wire 135, and the second contact plug 136 may each include at least one of copper, aluminum, tungsten, nickel, gold, tin, titanium, and alloys thereof.

The connection pad 137 in the first region R1 is disposed between the first contact plug 133 and the ground connection member 138G, or between the second contact plug 136 and the dummy connection member 138D. The connection pad 137 in the first region R1 connects the first contact plug 133 to the ground connection member 138G, or the second contact plug 136 to the dummy connection member 138D. In an embodiment, the connection pad 137 in the first region R1 may include at least one of copper, nickel, zinc, gold, silver, platinum, palladium, chromium, titanium, and alloys thereof.

The electric power through silicon via 132P of the first region R1 is placed between a first bonding pad 141 of the interconnection structure 140 and the connection pad 137. The electric power through silicon via 132P of the first region R1 electrically connects the first bonding pad 141 of the interconnection structure 140 to the connection pad 137. The electric power through silicon via 132P of the first region R1 supplies electric power transmitted through a first electric power via 112P of the substrate 110, the electric power wiring line 113P of the substrate 110, the second electric power via 114P of the substrate 110, and the electric power connection member 138P to the logic die 150. The electric power through silicon via 132P of the first region R1 is not electrically connected to the defective capacitor structure 210.

The normal capacitor structure 220 is connected to the electric power wiring line 113P of the substrate 110. The normal capacitor structure 220 is electrically connected to the electric power through silicon via (second through silicon via) 132P disposed in the same second region R2 as the normal capacitor structure 220. The normal capacitor structure 220 is electrically connected to the logic die 150 through the electric power wiring line 113P of the substrate 110 and the electric power through silicon via 132P in the second region R2. The normal capacitor structure 220 is connected to the first contact plug 133, and subsequently connected to the ground through the connection pad 137, the ground connection member 138G, the second ground via 114G of the substrate 110, the ground wiring line 113G of the substrate 110, and the first ground via 112G of the substrate 110. The normal capacitor structure 220 is electrically connected to the contact wire 135, and receives electric power through the contact wire 135, the second contact plug 136, the connection pad 137, the electric power connection member 138P, the second electric power via 114P of the substrate 110, the electric power wiring line 113P of the substrate 110, and the first electric power via 112P of the substrate 110.

The first contact plug 133 in the second region R2 is placed between the normal capacitor structure 220 and the connection pad 137. The first contact plug 133 in the second region R2 electrically connects the normal capacitor structure 220 to the connection pad 137. The contact wire 135 in the second region R2 is placed between the normal capacitor structure 220 and the second contact plug 136. The first contact wire 135 in the second region R2 electrically connects the normal capacitor structure 220 to the second contact plug 136. The second contact plug 136 in the second region R2 is placed between the contact wire 135 and the connection pad 137. The second contact plug 136 in the second region R2 electrically connects the contact wire 135 to the connection pad 137. In an embodiment, the first contact plug 133, the contact wire 135, and the second contact plug 136 may each include at least one of copper, aluminum, tungsten, nickel, gold, tin, titanium, and alloys thereof.

The connection pad 137 in the second region R2 is disposed between the first contact plug 133 and the ground connection member 138G, or between the second contact plug 136 and the electric power connection member 138P. The connection pad 137 in the second region R2 electrically connects the first contact plug 133 to the ground connection member 138G, or the second contact plug 136 to the electric power connection member 138P. In an embodiment, the connection pad 137 in the second region R2 may include at least one of copper, nickel, zinc, gold, silver, platinum, palladium, chromium, titanium, and alloys thereof.

The electric power through silicon via 132P of the second region R2 is placed between the first bonding pad 141 of the interconnection structure 140 and the connection pad 137. The electric power through silicon via 132P of the second region R2 electrically connects the first bonding pad 141 of the interconnection structure 140 to the connection pad 137. The electric power through silicon via 132P of the second region R2 supplies electric power transmitted through the first electric power via 112P of the substrate 110, the electric power wiring line 113P of the substrate 110, the second electric power via 114P of the substrate 110, and the electric power connection member 138P to the logic die 150. The electric power through silicon via 132P of the second region R2 is electrically connected to the normal capacitor structure 220 such that the power integrity (PI) of the logic die 150 can be improved.

The signal through silicon via 132S is placed within the capacitor die 130 without distinguishing between the first region R1 and the second region R2. The signal through silicon via 132S is placed between the first bonding pad 141 of the interconnection structure 140 and the connection pad 137. The signal through silicon via 132S electrically connects the first bonding pad 141 of the interconnection structure 140 to the connection pad 137. The signal through silicon via 132S has a function of transmitting signals between the logic die 150 and an external device through the first signal via 112S of the substrate 110, the signal wiring line 113S of the substrate 110, the second signal via 114S of the substrate 110, and the signal connection member 138S.

The interconnection structure 140 is placed between the capacitor die 130 and the logic die 150. The interconnection structure 140 includes the first bonding pads 141 and a first silicon insulation layer 143 on an upper surface of the capacitor die 130, and a second bonding pads 142 and a second silicon insulation layer 144 on a bottom surface of the logic die 150. The first bonding pad 141 is directly bonded to the second bonding pad 142 by metal-metal hybrid bonding, and the first silicon insulation layer 143 is directly bonded to the second silicon insulation layer 144 by non-metal-non-metal hybrid bonding. In another embodiment, the interconnection structure 140 may include connection members (e.g., micro bumps) and insulating members (e.g., non-conductive film (NCF)) surrounding the connection members.

The logic die 150 is placed on the interconnection structure 140. The logic die 150 is electrically connected to the normal capacitor structure 220 only through the electric power through silicon via 132P placed in the second region R2 and the electric power wiring line 113P of the substrate 110. In an embodiment, the logic die 150 may include a system on chip (SoC). In an embodiment, the logic die 150 may include an application processor (AP). In an embodiment, the logic die 150 may include at least one of a central processing unit (CPU) and a graphics processing unit (GPU).

The connection members 138 are disposed between the substrate 110 and the 3DIC structure 120. Each of the connection members 138 is disposed between the bonding pad 115 of the substrate 110 and the connection member 137 of the capacitor die 130. Each of the connection members 138 electrically connects the connection member 137 of the capacitor die 130 to the bonding pad 115 of the substrate 110. In an embodiment, the connection member 138 may include a micro bump or solder ball. In an embodiment, the connecting member 138 may include at least one of tin, silver, lead, nickel, copper, or an alloy thereof.

Each of the connection members 138 is the ground connection member (ground bump) 138G, the electric power connection member (electric power bump) 138P, the signal connection member (signal bump) 138S, or the dummy connection member (dummy bump) 138D. The electric power connection member 138P is electrically connected to electric power through silicon via 132P in the first region R1, the electric power through silicon via 132P in the second region R2, and the normal capacitor structure 220. The signal connection member 138S is electrically connected to the signal through silicon via 132S. The dummy connection member 138D physically bonds the defective capacitor structure 210 to the substrate 110. The dummy connection member 138D is electrically separated from the electric power through silicon via 132P in the first region R1.

The insulating member 160 is disposed between the substrate 110 and the 3DIC structure 120. The insulating member 160 surrounds and protects the bonding pads 115, the connection pads 137, and the connection members 138. In an embodiment, the insulation member 160 may include a capillary underfill (CUF). In an embodiment, the insulating member 160 may include a non-conductive film (NCF). In one embodiment, the insulating member 160 may include non-conductive paste (NCP).

FIG. 6 is a cross-sectional view of the capacitor structure 200 according to an embodiment of the present invention.

Referring to FIG. 6, the capacitor structure 200 includes the lower plate layer 239, the lower electrode 221, the dielectric layer 222, the upper electrode 223, the interconnection member 230, and the upper plate layer 240. The present disclosure describes and illustrates an integrated stack capacitor (ISC). However, in another embodiment, the capacitor structure 200 may include a metal-insulator-metal (MIM) capacitor or a deep trench capacitor (DTC). In the embodiment of FIG. 6, the capacitor structure 200 where four through-holes and the lower electrode 221, the dielectric layer 222, and the upper electrode 223 are continuously formed around the through-holes is illustrated. However, the capacitor structure 200 can include tens of thousands of through-holes, with the lower electrode 221, the dielectric layer 222, and the upper electrode 223 continuously formed around them.

An integrated stack capacitor (ISC) according to the present disclosure features a 3-dimensional capacitor structure arranged both horizontally and vertically. A capacitor is formed vertically along an inner surface of each of the through-holes, and these capacitors are arranged horizontally in a continuous manner. Therefore, the integrated stack capacitor according to the present disclosure may have capacitance more than 10 times that of conventional capacitors.

The lower plate layer 239 is placed at the bottom of the capacitor structure 200. The lower plate layer 239 electrically connects the lower electrode 221 to the first contact plug 133 (refer to FIG. 5). In an embodiment, the lower plate layer 239 may include TiN.

The lower electrode 221 is disposed on the lower plate layer 239. The lower electrode 221 is in direct contact with the lower plate layer 239. The lower electrode 221 extends conformally along the interior of the through-holes (an upper surface of the lower plate layer 239 and an inner surface of the through-hole) and along the upper surface of the dielectric material 131 around the through-holes. The lower electrode 221 penetrates the dielectric material 131 and contacts the lower plate layer 239, and is electrically connected to the lower plate layer 239. In an embodiment, the lower electrode 221 may have a vertical cylinder shape. In an embodiment, the lower electrode 221 may have a truncated circular cone shape. In an embodiment, the lower electrode 221 may include a metal nitride layer, a metal oxide layer, a metal acid nitride layer, or a combination thereof. In an embodiment, the lower electrode 221 may include TiN, CON, NbN, SnO₂, or a combination thereof.

The dielectric layer 222 extends conformally on the lower electrode 221 and along the lower electrode 221. In an embodiment, the dielectric layer 222 may have a vertical cylinder shape. In an embodiment, the dielectric layer 222 may have a truncated circular cone shape. In an embodiment, the dielectric layer 222 may include a metal oxide layer. In an embodiment, the dielectric layer 222 may include AlO₂, ZrO₂, HfO₂, Nb₂O₅, CeO₂, TiO₂, or a combination thereof. In an embodiment, the dielectric layer 222 may include a multi-layered film in which AlO₂ and ZrO₂ are alternately stacked.

The upper electrode 223 extends conformally along the dielectric layer 222 on the dielectric layer 222. The upper electrode 223 is in direct contact with the interconnection member 230. For example, the upper electrode 223 is in contact with the interconnection member 230 and is electrically connected to the interconnection member 230. In an embodiment, the upper electrode 223 may have a vertical cylinder shape. In another embodiment, the upper electrode 223 may have a truncated circular cone shape. In an embodiment, the upper electrode 223 may include a metal nitride layer, a metal oxide layer, a metal oxynitride layer, or a combination thereof. In an embodiment, the upper electrode 223 may include TiN, CON, NbN, SnO₂, or a combination thereof.

The interconnection member 230 is disposed between the upper electrode 223 and the upper plate layer 240. The interconnection member 230 electrically connects the upper plate layer 240 to the upper electrode 223. The interconnection member 230 includes embedded plugs 230A and plate member 230B. The embedded plugs 230A are embedded in the through-holes on the upper electrode 223. The plate member 230B is placed on the upper electrode 223, extending horizontally, and electrically connects the upper plate layer 240 to the embedded plugs 230A. The embedded plugs 230A and the plate member 230B of the interconnection member 230 are made of a single material and may be integrally formed.

The upper plate layer 240 is disposed between the interconnection member 230 and the second contact line 135. The upper plate layer 240 electrically connects the second contact line 135 to the interconnection member 230. In an embodiment, the upper plate layer 240 may include TiN.

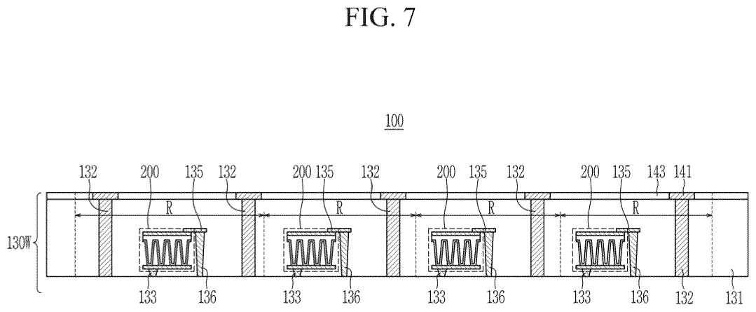

FIG. 7 to FIG. 13 are cross-sectional views provided to describe a method for manufacturing the semiconductor package 100 of FIG. 5.

FIG. 7 is a cross-sectional view of steps for providing the wafer 130W including the capacitor dies 130.

Referring to FIG. 7, the wafer 130W including the capacitor dies 130 is provided. Each of the capacitor dies 130 includes capacitor structures 200 and electric power through silicon vias 132P. Each of the capacitor structures 200 and each of the electric power through silicon vias 132P are disposed within each of the regions R defined by dividing the plane of the capacitor die 130.

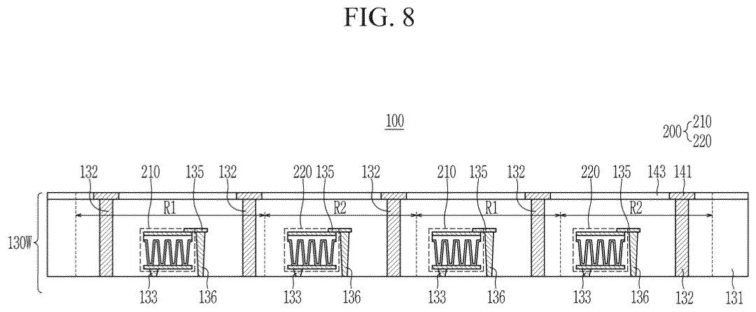

FIG. 8 is a cross-sectional view of steps for performing an EDS process on the capacitor structures 200.

Referring to FIG. 8, an EDS process is performed on each of the capacitor structures 200 within the wafer 130W to determine whether the singulated capacitor structures 200 have a defect D. After performing the EDS process, a capacitor structure 200 determined to be defective is defined as a defective capacitor structure 210, while a capacitor structure 200 determined to be non-defective is defined as a normal capacitor structure 220. A region R where the defective capacitor structure 210 is disposed is defined as a first region R1, and a region R where the normal capacitor structure 220 is disposed is defined as a second region R2.

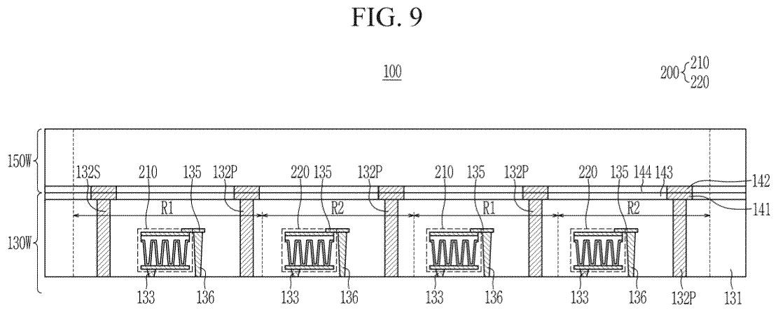

FIG. 9 is a cross-sectional view of steps for bonding the first wafer 130W and a second wafer 150W.

Referring to FIG. 9, hybrid bonding is performed to bond the first wafer 130W and the second wafer 150W. A first bonding pad 141 of the first wafer 130W and a second bonding pad 142 of the second wafer 150W are directly connected by metal-metal hybrid bonding. Metal bonding occurs at an interface between the first bonding pad 141 of the first wafer 130W and the second bonding pad 142 of the second wafer 150W by metal-metal hybrid bonding. In an embodiment, the first bonding pad 141 and the second bonding pad 142 may include copper. In another embodiment, the first bonding pad 141 and the second bonding pad 142 may be made of metallic materials capable of hybrid bonding.

The first bonding pad 141 of the first wafer 130W and the second bonding pad 142 of the second wafer 150W are made of the same material, and after hybrid bonding, an interface between the first bonding pad 141 of the first wafer 130W and the second bonding pad 142 of the second wafer 150W may disappear. The capacitor die 130 and the logic die 150 are electrically connected to each other by bonding the first bonding pad 141 of the first wafer 130W and the second bonding pad 142 of the second wafer 150W.

The first silicon insulation layer 143 of the first wafer 130W and the second silicon insulation layer 144 of the second wafer 150W are directly connected by non-metal-non-metal hybrid bonding. A covalent bond is formed at the interface between the first silicon insulation layer 143 of the first wafer 130W and the second silicon insulation layer 144 of the second wafer 150W by the non-metal-non-metal hybrid bonding.

In an embodiment, the first silicon insulation layer 143 and the second silicon insulation layer 144 may include a silicon oxide or a TEOS forming oxide. In an embodiment, the first silicon insulation layer 143 and the second silicon insulation layer 144 may include SiO₂. In another embodiment, the first silicon insulation layer 143 and the second silicon insulation layer 144 may be silicon nitride, silicon oxynitride, or other suitable dielectric material. In another embodiment, the first silicon insulation layer 143 and the second silicon insulation layer 144 may include SiN or SiCN.

The first silicon insulation layer 143 of the first wafer 130W and the second silicon insulation layer 144 of the second wafer 150W are formed of the same material, and after hybrid bonding, the interface between the first silicon insulation layer 143 of the first wafer 130W and the second silicon insulation layer 144 of the second wafer 150W may disappear.

In another embodiment, the second wafer 150W may be bonded to the first wafer 130W by flip chip bonding.

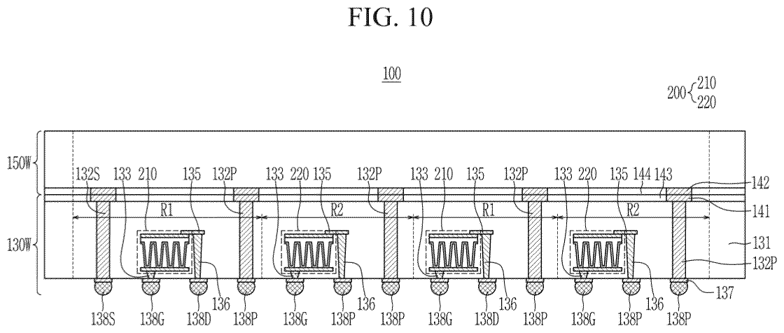

FIG. 10 is a cross-sectional view of steps for forming the connection pads 137 and the connection members 138 in the bottom surface of the wafer 130W.

Referring to FIG. 10, the connection pads 137 are formed on the bottom surface of the wafer 130W (bottom surface of the capacitor die 130), and the connection members 138 are formed below the connection pads 137. In an embodiment, the connection pad 137 may be formed by performing a sputtering process, or an electrolytic plating process after forming a seed metal layer.

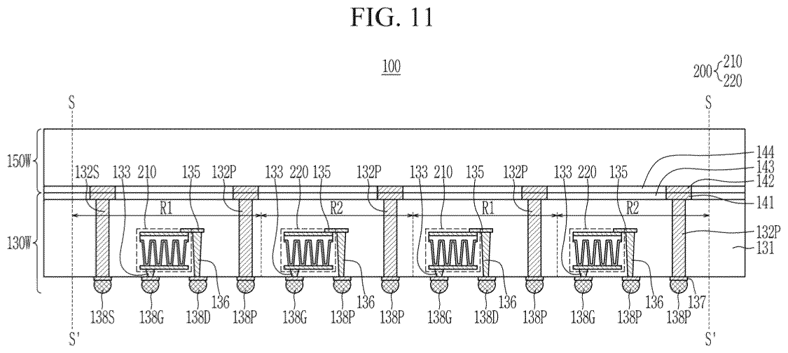

FIG. 11 is a cross-sectional view of steps for singulation of the bonded wafer structure.

Referring to FIG. 11, the wafer structure formed by bonding the wafer 130W and the wafer 150W is singulated. The singulation proceeds along the scribe line S-S′. After the singulation, 3DIC structures 120 are formed.

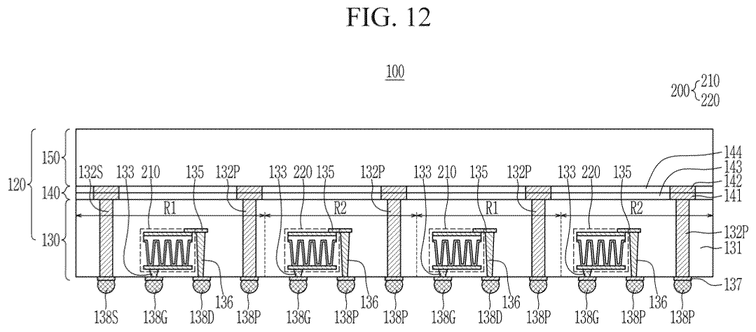

FIG. 12 is a cross-sectional view of the 3DIC structure 120 after the singulation.

Referring to FIG. 12, the 3DIC structure 120 is formed after the singulation. The 3DIC structure 120 includes a capacitor die 130, an interconnection structure 140, and a logic die 150. The capacitor die 130 does not include a configuration that can directly electrically connect the capacitor structure 200 to the logic die 150.

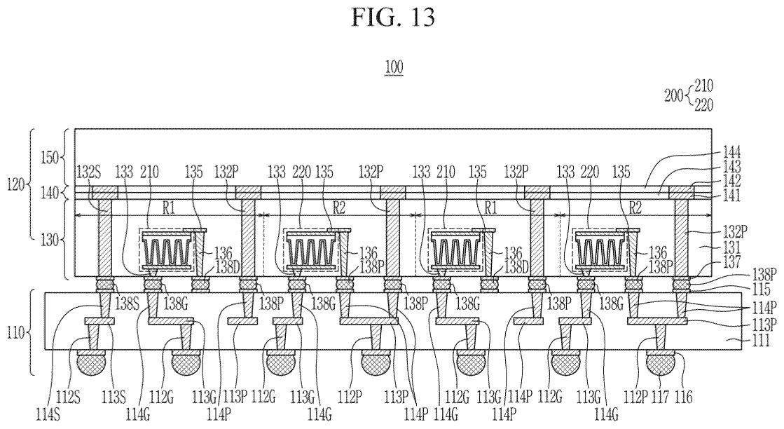

FIG. 13 is a cross-sectional view of steps for installing the 3DIC structure 120 on the substrate 110.

Referring to FIG. 13, the 3DIC structure 120 is mounted on the substrate 110 by performing a flip chip bonding process. Subsequently, the insulating member 160 (refer to FIG. 5) is applied between the 3DIC structure 120 and the substrate 110, or a molding material may be used to cover the 3DIC structure 120 on the substrate 110. The substrate 110 includes an electric power wiring line 113P that can electrically connect the normal capacitor structure 220 and the logic die 150, but it does not include a wiring line 113 that can electrically connect a defective capacitor structure 210 and the logic die 150. In an embodiment, the substrate 110 including the wiring lines 113 may be manufactured in advance.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor package comprising:
a substrate that includes a wiring line; and
a 3-dimensional integrated circuit structure on the substrate, the 3-dimensional integrated circuit structure including a first die and a second die on the first die, the first die including a first capacitor structure having a defect, a second capacitor structure free of defects, and a plurality of through silicon vias connected to the second die,
wherein the first capacitor structure is electrically separated from the second die, and
the second capacitor structure is electrically connected to a corresponding through silicon via among the plurality of through silicon vias through the wiring line.

2. The semiconductor package of claim 1, wherein:
the first capacitor structure is connected only to a ground.

3. The semiconductor package of claim 1, wherein:
the second capacitor structure is connected to a ground and the wiring line.

4. The semiconductor package of claim 1, wherein:
the wiring line is an electric power wiring line.

5. The semiconductor package of claim 1, wherein:
the second die is electrically connected to the second capacitor structure only through a corresponding through silicon via among the plurality of through silicon vias and the wiring line.

6. The semiconductor package of claim 1, wherein:
the first capacitor structure and the second capacitor structure comprise an integrated stack capacitor structure.

7. The semiconductor package of claim 1, wherein:
the first capacitor structure and the second capacitor structure comprise a metal-insulator-metal (MIM) capacitor or a dip trench capacitor.

8. The semiconductor package of claim 1, wherein:
the second die is a logic die.

9. The semiconductor package of claim 1, wherein:
the substrate comprises a printed circuit board, a redistribution structure, or an interposer.

10. A semiconductor package comprising:
a substrate that includes one or more wiring lines; and
a 3-dimensional integrated circuit structure on the substrate,
wherein the 3-dimensional integrated circuit comprises:
a first die that includes one or more first capacitor structures, one or more second capacitor structures, one or more first through silicon vias, and one or more second through silicon vias, the first die including one or more first regions and one or more second regions defined by dividing the plane of the first die, each of the one or more first capacitor structures and each of the one or more first through silicon vias disposed in each of the one or more first regions, each of the one or more second capacitor structures and each of the one or more second through silicon vias disposed in each of the one or more second regions, the one or more first capacitor structures having a defect, and the one or more second capacitor structures being free of a defect; and
a second die on the first die, the second die connected to the one or more first through silicon vias and the one or more second through silicon vias,
the first capacitor structure and the first through silicon via in each of the one or more first regions are electrically separated from each other, and
the second capacitor structure and the second through silicon via in each of the one or more second regions are electrically connected through each of the one or more wiring lines.

11. The semiconductor package of claim 10, further comprising a plurality of bumps between the substrate and the first die,
wherein each of the plurality of bumps is a ground bump, an electric power bump, a signal bump, or a dummy bump.

12. The semiconductor package of claim 11, wherein:
each of the one or more first capacitor structures is connected to the ground bump and the dummy bump.

13. The semiconductor package of claim 12, wherein:
the dummy bump bonds each of the one or more first capacitor structures to the substrate and is electrically separated from each of the one or more first through silicon vias.

14. The semiconductor package of claim 11, wherein:
each of the one or more second capacitor structures is connected to the electric power bump.

15. The semiconductor package of claim 11, wherein:
each of the one or more first through silicon vias and the one or more second through silicon vias are connected to the electric power bump.

16. The semiconductor package of claim 11, wherein:
the first die comprises a plurality of third through silicon vias, and
each of the plurality of third through silicon vias is connected to the signal bump.

17. A semiconductor package manufacturing method comprising:
forming a plurality of capacitor dies in a first wafer, each of the plurality of capacitor dies including a plurality of capacitor structures and a plurality of through silicon vias;
determining whether each of the plurality of capacitor structures has a defect;
bonding a second wafer that includes a plurality of logic dies to the first wafer, each of the plurality of logic dies connected to the plurality of through silicon vias;
forming a 3-dimensional integrated circuit structure by singulating the bonded first and second wafers;
providing a substrate where a defective capacitor structure is connected only to a ground and a defect-free capacitor structure is electrically connected to a corresponding through silicon via among the plurality of through silicon vias; and
bonding a 3-dimensional integrated circuit structure on the substrate.

18. The semiconductor package manufacturing method of claim 17, wherein:
the determining whether each of the plurality of capacitor structures has the defect is performed by an electrical die sorting (EDS) process.

19. The semiconductor package manufacturing method of claim 17, wherein:
the bonding the second wafer to the first wafer is performed by a hybrid bonding process.

20. The semiconductor package manufacturing method of claim 17, wherein:
in the providing the substrate, the substrate is selected from among pre-manufactured substrates.
